(19) United States
(12) Patent Application Publication
(10) Pub. No.: US 2003/0073042 A1
(43) Pub. Date: Apr. 17, 2003

(54) Process and materials for formation of patterned films of functional materials

(76) Inventors: George J. Cernigliaro, Freeport, ME (US); Roger F. Sinta, Woburn, MA (US)

Correspondence Address: Robert G. Rosenthal, Law Office of Robert G. Rosenthal, Suite 200, 5856 Faringdon Place, Raleigh, NC, 27609, US

(21) Appl. No.: 09/981,527

(22) Filed: Oct. 17, 2001

(51) Int. Cl. G03F 7/00; G02F 1/133

(52) U.S. Cl. 430/321; 430/270.1; 430/311; 430/198; 430/325

(57) ABSTRACT

The invention is for a method and composition for forming one or more patterned layers of functional material over a substrate. The method comprising providing a coating composition comprising a photopatterning material containing a particulate filler of a functional material. The particulate filler is one that is essentially transparent to activating radiation. Once formed, the coating is exposed to activating radiation in an image pattern and developed to form the patterned layer of functional material. The organic components of the coating can be removed if desired.

### BACKGROUND OF THE INVENTION

1. Introduction

This invention relates to the patterning of functional materials for electronic component manufacture. More particularly, this invention relates to a simplified process for the formation of patterned layers of functional materials using high resolution imaging systems filled with large concentrations of functional materials in particulate form and of nanosize dimension.

2. Description of the Prior Art

Patterned layers of functional materials are used extensively in electric component manufacture as well as for many other purposes. As an example, multiple layers of differing patterned layers of such materials are used extensively in the manufacture of flat panel displays (FPDs), such as liquid crystal displays (LCDs). LCDs have become an increasingly important device in today's computer age. They have several distinct advantages over cathode ray tubes including the absence of radiation and substantially lower power consumption. Because of their better brightness and wider viewing angle, active matrix liquid crystal displays (AMLCD) have become the preferred LCD.

An AMLCD generally comprises a plurality of rows and columns of address lines, which cross at an angle to one another, thereby forming a plurality of crossover points. A pixel is an array element associated with each crossover point that can be selectively addressed. A patterned black matrix typically separates individual display pixels. Typically a switching device such as a thin film transistor (TFT) is associated with each array element or pixel. The switching devices allow the individual pixels to be selectively accessed by the application of suitable voltage between respective pairs of row and column address lines so as to allow images to be shown on the screen. A TFT generally contains a pair of substantially co-planar source and drain electrodes, a thin film semiconductor material disposed between the source and drain electrodes, and a gate electrode in proximity to the semiconductor but electrically insulated therefrom by a gate insulator. An application of voltage to the gate electrode controls the current flow through the TFT between the pair of source and drain electrodes. This causes the associated pixel of an AMLCD to be switched on and off.

To construct an AMLCD, it is necessary to form high-resolution patterned films of functional materials for many of the elements described above. For example, the pixels, the associated TFT layers, and the black matrix are all in the form of patterned thin films having feature sizes of anywhere from 5 to 100 μm, and preferably 5-40 μm in order to produce a screen image having desired image clarity and definition. Typically, photolithographic procedures are used to form these patterned thin films. An example of a generalized photolithographic process used in the manufacture of AMLCDs is shown in FIGS. 1(a) through 1(d) of the drawings.

In the process depicted in FIG. 1(a), a transparent support 100 is coated with a desired layer of functional material 101 as a continuous thin film. The functional material may be any of the functional materials used for ANMCD construction as will be discussed in greater detail below. The method of deposition is dependent upon the material used. For example, if the process were used to pattern the TFT layer, the functional material would be a semiconductor material such as an indium tin oxide (ITO) or a tin oxide layer and would be typically applied by chemical vapor deposition. With reference to FIG. 1(b), following deposition of the functional material, it would be coated with a layer of high-resolution photoresist 102. The photoresist would then be imaged by exposure to patterned radiation using photomask 103 having opaque and transparent portions to form a latent image within the photoresist coating 102 comprising areas 104 soluble in developer and areas 105 insoluble in developer. Following exposure, photoresist coating 102 would be developed to form a relief image with the insoluble regions 105 defining a mask over functional material layer 101 as shown in FIG. 1(c). By formation of the relief image, portions of the functional material layer 101 are bared for further treatment. As shown in FIG. 1(d), the additional treatment comprises removal of the functional material where bared so as to form the desired thin patterned layer of functional material 101. The method of removal is dependent upon the particular functional material used. Most often, removal would be by etching. Following the etching step, the remaining photoresist layer 102 would be removed, for example, by treatment with a solvent.

There are many uses of patterned layers of functional materials in addition to AMLCD construction. These uses include, but are not limited to:

a. a film of catalytic material for continuous stream catalysis such as a microfluidic process where, for example, a patterned surface of catalytic platinum or palladium over a substrate such as graphite, may be used to catalyze the hydrolysis of water during use of a fuel cell;

b. formation of photonic devices such as quantum hetero-structure devices and chemical sensors;

c. formation of multilayer structures such as for use in magnetoresistive applications, computer memory, and thin film head applications;

d. semiconductor fabrication such as for catalytic doping sites for gaseous materials in a directed stream;

e. direct stream purification of gases;

f. printed circuit fabrication where plasma or thermal treatment may be used to remove photochemical residues from a patterned film leaving a patterned film of a metal such as Cu, Ni, Pd, Pt, Sn, Co, B, and/or their oxides;

g. fabrication of high electrical resistance ceramic films, such as barrier ribs segregating plasma wells used in plasma display pixels;

h. fabrication of direct patterned superconductor films;

i. fabrication of both ceramic and metallic patterned films in a variety of dispersed matrices for enhancement of mechanical strength, corrosion, and wear resistance;

j. fabrication of alternating patterned layers of magnetic materials, such as Fe and Cr, for magnetic multilayer devices;

k. deposition of dispersions of n or p dopants, such as dispersions of B or P derivatives or their precursors onto a semiconductor substrate; to pattern 2-D (conventional lithography) or 3-D (stereolithography) structures with special chemical and/or physical properties conferred by appropriate patterned layers such as those patterned with standard microelectromechanical machining (MEMS) processes, or surface micromachining (LIGA) processes;

l. formation of patterned layers of phosphors for cathode ray tubes and flat panel devices such as field emission displays, electroluminescent displays, plasma displays, organic light emitting displays. as well as other displays using phosphors as the light emissive mechanism, and

m. patterned layers used for permanent dielectric films such as used in integrated circuit and flat panel display devices.

Regardless of the intended use of a patterned film of a functional material, the process for its formation, exemplified by the process described above in reference to FIG. 1, is lengthy and time consuming. Moreover, for many of the uses identified, such as in AMLCD construction, the process must be repeated multiple times. For example, with further reference to AMLCD construction, to form the pixel layer, the process must be repeated three times, once for each of the primary colors. In addition, the process must be used for formation of the TFT layer, insulating layers, the black matrix layer, etc.

Efforts have been made in the prior art to develop a process for formation of high-resolution patterned layers of functional materials requiring substantially fewer processing steps. One such process is disclosed in U.S. Pat. No. 5,639,579 incorporated herein by reference. In accordance with the process of this patent, color filter layers for liquid crystal displays are formed using a photosensitive colored resin composition comprising (a) a resin-based material hardenable with an acid, (b) a photoreactive acid-releasing agent, and (c) a pigment. The layers are formed using a method comprising the steps of:

(1) coating a negative-tone photosensitive colored resin composition comprising (a) a resin-based material hardenable with an acid, (b) a photoreactive acid-releasing agent, and (c) a pigment on a transparent substrate, and drying the coating to form a colored resin layer;

(2) pattern exposing the colored resin layer;

(3) heating the exposed colored resin layer; and

(4) developing the exposed and heated colored resin layer with an alkaline developing solution to form a colored image on the transparent substrate.

The steps of the above-described process are repeated as many times as necessary to form aligned multi-colored patterns on the same substrate. In addition to the process of forming the pigmented resin layers, the patent also teaches a similar process for formation of a black matrix for the fabrication of a color filter on a transparent substrate comprising the steps of:

(1) coating a photosensitive black resin composition using the photoimaging material described above and drying the coating to form a black resin layer;

(2) pattern exposing the black resin layer;

(3) heating the exposed black resin layer; and

(4) developing the exposed and heated black resin layer.

The above process reduces the number of steps required to form a color filter. However, the process is commercially limited, as image resolution is inadequate resulting in pixels that are too large or too poorly defined for advanced color filter applications.

### SUMMARY OF THE INVENTION

The subject invention provides simplified processes for the formation of patterned layers of functional materials using high resolution imaging systems filled with large concentrations of functional materials in particulate form and of nanosize dimension. The process may be used to form any device requiring the use of a patterned layer of a functional material. In a preferred embodiment, the process of the invention is used for the formation of multiple patterned layers of functional materials for the fabrication of FPDs.

The process of the invention uses a cast film material comprised of functional nanoparticle filler(s) and light sensitive patterning chemistry, preferably negative tone patterning chemistry. A film of this material is one that can be exposed to spatially modulated activating radiation, such as through a mask, and developed to yield a relief image pattern. For purposes of the invention, the photochemistry suitable for high-resolution photoresist compositions could be used, such as that based upon the use of chemically amplified photoacid generators (PAGs).

The nanoparticle filler within the photopatterning chemistry is selected depending upon the use of the patterned layer to be formed. For example, if the patterned layer is to be a color filter for an AMLCD, or an emitting phosphor layer for a field emission or plasma display, then the nanoparticle filler could be a pigment or a phosphor. If the functional layer is conductive, such as for address electrodes for a thin film transistor (TFT), then the nanoparticle filler might be a semiconducting material such as indium tin oxide or tin oxide.

Mask-wise exposure of a substrate coated with the photoactive nanoparticle film to activating radiation provides a latent image within the coating in conformity with the pattern of activating radiation. Development of the nanoparticle coating containing the latent image results in formation of the patterned nanoparticle layer on the substrate surface. The resulting relief pattern within the layer is dependent upon (1) the resolution capability of the mask used to image the photoactive coating, (2) the resolution capability of the photoactive coating, (4) the exposure tool, and (3) the thickness of the coating. Coating thickness can be easily controlled whether the film is applied in dry form or as a liquid coating composition.

It is known in the art that current photoresist compositions are capable of high-resolution images, substantially greater than images formed using filled screen pastes or etching techniques. Photoresists may be used in the process of the subject invention. However, where etching of a substrate is generally not required in accordance with the subject invention, there is greater compositional latitude in the formation of the photopatterning chemistry as will be discussed in greater detail below. Any one or more patterned layers can be formed on a surface of a device using the procedures of this invention.

As will be explained in greater detail below, the invention in part resides in the ability to form high-resolution images using photoactive compositions filled with nano-sized particles. In this respect, it has been found that high-resolution patterns can be formed using chemically amplified photoactive compositions containing high loadings of filler in nano particle dimension. Preferably, the particles are of uniform size and shape. With suitably sized fine particles having other desirable properties, filler content can be as high as 90 percent of the total composition. Following formation of the patterned layer, if desired, the organic components may be removed by ablation, preferably using rapid thermal processing procedures as will be described in greater detail below.

The process of the invention may be part of a total process for formation of a device using sequential coating and imaging steps. With respect to FPD fabrication, such as for AMLCD for purposes of exemplification, the process would comprise formation of ITO layers, insulating layers, color pigmnent layers and black matrix layers.

### DESCRIPTION OF THE DRAWINGS

FIGS. 1(a) through 1(d) of the drawings represents a sequence of steps for AMLCD construction using prior art procedures as descirbed above; and

FIGS. 2(a) through (c) of the drawings represents a sequence of steps for AMLCD construction using the processes of the invention.

### DEFINITIONS

The term “functional material” as used herein means a particulate composition or composite using nano-sized particles of specific size and shape, and having functional properties consistent with a desired use or device, due to the combination of particle chemistry, physical size and shape of the particle, such as, for example, electrical conductance, electrical resistance, light emission, color saturation properties, etc.

The term “photopatterning composition” as used herein means a light sensitive composition that may be exposed to activating radiation and developed to yield a relief image. The term includes known photoresists within its scope but also includes photosensitive compositions that do not require the etch resistance of a conventional photoresist.

### DESCRIPTION OF THE PREFERRED EMBODIMENTS

The discussion that follows first describes the requirements for the fillers for the filled photopatterning compositions suitable for fabrication of devices in accordance with the invention. Thereafter, suitable photopatterning compositions and fillers will be described. Finally, the fabrication of a hypothetical device fabricated in accordance with the procedures of the invention will be described. This will be followed by suitable examples of depicting compositions and processing steps.

a. Filled Photopatterning Compositions—Physical Requirements

Photopatterning compositions, especially photoresists, are well known in the art. These materials are applied to a surface to form a coating by casting from solution and drying, or by application of a dry film of the coating material. The coating is capable of exposure and development to yield a relief image. Photoresists are used for the fabrication of circuit boards, semiconductors, FPDs, etc. The resolution capability of a photoresist used to fabricate semiconductors or some special types of FPDs requires submicron imaging capability.

It has been understood in the art that to obtain high-resolution images, the photopatterning composition should be free of impurities, especially particulates, as particulates scatter light during exposure. Light scattering is known to result in a loss of pattern resolution due to undesired over-exposure of imaged portions of the coating and exposure of non-imaged portions of the coating. Consequently, the solubility properties of the coating of the photopatterning composition change in areas where development is undesired.

Where particulates contained in photopatterning compositions are undesirable, it would appear contraindicated to fill such a composition with particulate filler, as it would be expected that the filler would cause light scattering with concomitant loss of image resolution. However, Rayleigh's equation for light scattering using incident unpolarized light striking spherical particles is a function of many factors and is directly proportional to the cube of the mean diameter of the particles. From Rayleigh's equation, it follows that the larger the particle, the greater will be the scattering of light. Conversely, as the particle diameter decreases, scattering is decreased to a point where the particle becomes virtually transparent to incident light—i.e., there is minimal interaction of light with the particle.

From Rayleigh's equation, it is predicted that it is possible to form high-resolution images using coatings of filled photopatterning composition, if the filler meets certain physical requirements. The requirements for a filler in a photoresist composition are disclosed in U.S. Pat. Nos. 5,639,579; 5,871,872; 5,885,343; and 6,183,935 directed to formation of color filter photoresists, and incorporated herein by reference for their teaching of obtaining high resolution images from filled photoresist systems.

To obtain a high-resolution image, it is necessary that photopatterning compositions containing filler be essentially transparent to activating radiation. To achieve transparency, it is necessary that the filler be particulate, be of small dimension, be relatively uniform in size and shape, in some cases, for all but a few applications, be of low refractive index, and be fully and uniformly dispersed in the photopatterning coating composition. For fabrication of devices having high resolution layers, in accordance with the invention, it is desirable that the filler particles have an average diameter less than about 100 nm, preferably less than 50 nm, more preferably a diameter between 5 nm and 40 nm, and most preferably, a diameter between 5 nm and 20 nm. In addition, it is desirable that the total surface area of the particles be between 30 and 1,000 m²/g, more preferably, between 80 and 500 m²/g. In addition, it is desirable that the refractive index of the particulates be low. The filler may be contained within the photopatterning composition in an amount up to 90 percent by weight of the composition, preferably in an amount of from 10 to 90 percent, and more preferably, in an amount of from 25 to 80 percent. The actual content of the filler in the photopatterning composition is in part dependent upon the materials used and its properties such as particle size, refractive index, surface area, etc.

As described above, the physical properties of the particulates coupled with the resolution capability of the photopatterning composition govern resolution capability of an exposed and developed coating containing filler. For fabrication of all devices, the lower the particle size and the higher the resolution capability of the photopatterning composition, the better will be the resolution capability of the filled coating.

Processes for formation of particles having the properties set forth above are disclosed in U.S. Pat. Nos. 5,318,797 and 5,344,489; and in J. Mater. Res., Vol 10, No. 12, December 1995, pp 3106 to 3114; J. Mater. Res., Vol 11, No. 1, January 1996, pp 156 to 161; and J. Mater. Res., Vol. 11, No. 12, December 1996, p3121 to 3127; all incorporated herein by reference. Double jet precipitation is the preferred method for making the filler particles, but other preparative methods may be employed consistent with the production of particles having the desired size and shape.

The method of blending the filler with the photopatterning composition is conventional and would be obvious to those skilled in the art.

b. The Photopatterning Composition

As stated above, the photopatterning composition is a light sensitive coating composition capable of imaging to form a latent image followed by development to yield a relief image. Photoresists are examples of suitable photopatterning compositions though photoresists are formulated to resist aggressive chemical treatment solutions such as etchants used for treatment of an underlying substrate. In accordance with the invention, for many applications, the underlying substrate is not treated and resistance to aggressive chemical treatment solutions is not required. This permits substantially greater latitude in the formulation of the photopatterning composition. For example, one can use a wide variety of spectrally transparent, non-aromatic polymers, which normally are not considered as strongly plasma etch resistant, but having the desired property of basic developer solubility. Examples include acrylic copolymers containing base-soluble functionality, such as carboxylic acid, sulfonic acid, reacted with other non-aromatic acrylic monomers designed to improve bulk film transparency, which promotes increased patterning resolution at exposing wavelengths, such as deep ultraviolet irradiation, normally limited by aromatic light absorbance.

Preferred photopatterning compositions useful for the processes of the invention are the acid hardening or chemically amplified photoresists as disclosed in U.S. Pat. Nos. 5,391,465; 5,639,579; 5,731,386; 5,827,634; 5,879,856; 5,968,712; and 6,203,965, each incorporated herein by reference for their teaching of photoresist compositions, methods for formulating the compositions and methods for using the same. Such photoresists may be negative-acting or positive-acting. They typically comprise a polymer binder and a photoactive generator that release an acid upon exposure to activating radiation. These materials rely upon multiple polymer crosslinking events in the case of a negative-acting resist, or deprotection reactions in the case of a positive-acting resist, per unit of a photogenerated acid that catalyzes the reaction.

To produce high-density devices, the industry is using shorter wavelength exposure sources and use deep U.V. radiation. Such photoresists offer the potential of forming images of smaller features than may be possible at longer wavelength exposure. As is recognized by those in the art, deep UV radiation refers to exposure radiation having a wavelength in the range of 350 nm or less, more typically in the range of 300 nm or less, such as radiation provided by a KrF excimer laser light (248 nm) or an ArF excimer laser light (193 nm).

The polymer binders suitable for the formation of the preferred photoresists include those containing base-soluble chemical functionality, hydroxyl and/or epoxy groups capable of acid catalyzed crosslinking, and film-forming ester functions. Specifically, acrylic polymers containing polar functional groups, including acidic functions, such as carboxylic acid, and/or hydroxyl functions, pendant ester moieties, as well as pendant epoxy. Other suitable classes of polymers include polyphenolics such as poly(vinylphenol)], and its derivatives, phenol, and/or cresylic formaldehyde condensates (novolaks) and their derivatives, including but not limited to, o-alkylated epoxyphenols and cresols. Yet another polymer class is the class of poly(amic acid)-imide polymers and/or fully imidized polymers, such as poly dimethyl glutarimides and its derivatives.

Specific examples of suitable polymers of the above type include a terpolymer of 15 mole percent methacrylic acid (MAA), 5 mole percent hydroxyethylmethacrylate (HEMA) and 80 mole percent butyl methacrylate, M_{W}=10,000-60,000; a tetrapolymer of 10 mole percent hydroxypropylmethacrylate (HPMA), 15 mole percent n-butyl methacrylate (NBMA), 20 mole percent MAA, 55 mole percent methyl methacrylate (MMA), M_{W}=20,000-60,000; a tetrapolymer of 10 mole percent MAA, 10 mole percent 2-epoxypropyl methacrylate, (EPMA), 40 mole percent NBMA, 40 mole percent MMA; M_{W}=10,000-60,000; a homopolymer of p(vinylphenol), M_{W} 3,000-20,000; copolymers of p(vinylphenol) and MMA and/or BMA, M_{W} 3,000-20,000; mixed ortho, meta, para cresol formaldehyde novolak polymer, M_{W}=5,000-20,000; and epoxynovolak polymer;, M_{W}=1,000-20,000.

As noted above, the preferred photoresists of the invention use one or more photoactive generators (PAGs). which upon exposure and baking diffuse acid through the film, generating more acid resulting from reaction with the polymer and in some cases, a crosslinker. The general classes of PAG chemistry include derivatives of bis-trichloromethyl triazine, biaryl iodonium salts, and triaryl sulfonium salts. These compounds are commercially available. Cationic crosslinking has advantages over free radical crosslinking, an alternative method for producing relief images. These advantages include insensitivity to oxygen, good shelf life, high imaging contrast with tunable photospeed, greater material flexibility in choosing base-soluble polymer binders, and non-tacky films before exposure permitting contact printing without mask-substrate sticking. These materials are used as photoimaging materials for color filter resists, and described in U.S. Pat. No. 5.639,579, and references cited therein. Electron transfer photosensitizers are sometimes employed to improve PAG photoresponse, depending on exposing wavelength. For example, phenothiazine and its derivatives may be used to improve the photosensitivity of a triazine PAG. Other direct energy transfer photosensitizers, such as polynuclear aromatic compounds, including but not limited to, anthracene an pyrene, and their derivatives, can also be used.

Examples of preferred PAGs include 2-(2′-furylethylidene)-4,6-bis(trichloromethyl)-s-triazine; 2-5′methyl-2′-furylethylidene)-4,6-bis(trichloromethyl)-striazine; 2-(3′,4′-dimethoxyphenylethylidene)-4,6-bis(trichloro-methyl)-s-triazine; 2,2′diphenyliodonium tosylate; triphenylsulfonium tosylate. Commercially available cationic photoinitiators, such as Union Carbide UVI-6992, UVI-6976; and Ciba Irgacure 291 may also be used.

The negative acting acid hardening photoresists utilize a crosslinking agent. Suitable acid catalyzed crosslinking chemistry is commercially available and materials suitable for purposes herein include melamine derivatives, such as hexamethoxymethyl melamine, mixed hexa-alkoxymethylmelamines, tetraalkoxyglycourils, and the like. These compounds are further described in U.S. Pat. No. 5,639,579 cited above together with the references cited therein. Specific examples include CYTEC Cymel 303 (hexamethoxymethyl melamine); CYTEC Cymel 303 ULF (hexamethoxymethyl melamine-ultra-low formaldehyde version); and CYTEC tetramethoxymethyl glycouril.

The photoresists are formulated by dissolution of the components in a solvent. Suitable solvents include glycol esters, preferably propylene glycol methylether acetate or 3-ethoxyethyl propionate, ethyl lactate and other less polar solvents as needed to stabilize the nanoparticle dispersion, which include cycloaliphatic ketones. Other additives, such as film leveling agents, dyes, or other compounds, may be added to enhance film performance, all as known by those skilled in the art and described in the above referenced patents.

The photopatterning compositions described above are the preferred materials for generating high resolution images. These materials would be used for the fabrication of devices such as LCDs. However, for some applications, high resolution is not a requirement. In these situations, other photopatterning chemistry may be used. For example, positive-working photoresists comprising a light-sensitive esters and amides of o-quinone diazide sulfonic acids and carboxylic acids in a film-forming novolak polymer binder may be suitable where high resolution is not a requirement. These esters and amides are well known in the art and are described by DeForest, Photoresist Materials and Processes, McGraw-Hill Book Company, New York, 1975, pp. 47-55, incorporated herein by reference. These light-sensitive compounds, and the methods used to make the same are all well documented and described in prior patents including German Patent No. 865,140 granted Feb. 2, 1953 and U.S. Pat. Nos. 2,767,092; 3,046,110: 3,046,112; 3,046,119; 3,046,121; 3,046,122; and 3,106,465, all incorporated herein by reference. Sulfonic amide sensitizers that have been used in the formulation of positive-acting photoresists are shown in U.S. Pat. No. 3,637,384, also incorporated herein by reference. These materials are formed by the reaction of a suitable diazide of an aromatic sulfonyl chloride with an appropriate resin amine. Methods for the manufacture of these sensitizers and examples of the same are shown in U.S. Pat. No. 2,797,213 incorporated herein by reference. Other positive-working diazo compounds have been used for specific purposes. For example, a diazo compound used as a positive-working photoresist for deep U.V. lithography is Meldrum's diazo and its analogs is described by Clecak et al., “Technical Disclosure Bulletin,” Volume 24, No. 4, September 1981, IBM Corporation, pp. 1907 and 1908, and o-quinone diazide compounds suitable for laser imaging as shown in U.S. Pat. No. 4,207,107. The aforesaid references are also incorporated herein by reference. Other patents illustrating such photoresist materials include U.S. Pat. Nos. 4,992,596; 5,912,102; and 5,932,389.

The resin binders most frequently used with the o-quinone diazides in commercial practice are the alkali-soluble phenol formaldehyde resins known as the novolak resins. Photoresists using such polymers are illustrated in U.K. Patent No. 1,110,017, incorporated herein by reference. These materials are the product of reaction of a phenol with formaldehyde, or a formaldehyde precursor, under conditions whereby a thermoplastic polymer is formed.

c. The Fillers

The nanoparticles used as fillers within the photopatterning materials described above are selected based upon the structure to be fabricated in accordance with the invention. Examples of specific applications and nanoparticles useful for these applications are given below.

Address electrodes and other conductive patterning dispersions: indium tin oxide [In₂O₃/SnO₂], tin oxide [SnO₂], and aluminum octoate [Al(OH)(C₇H₁₄COO]₂; (organometallic precursor to metallic aluminum); phosphors for CRT applications such as: Phosphor P1 [Zn₂SiO₄:Mn], Phosphor P22 Blue [ZnS:Ag], Phosphor P22 Green [ZnSCdS:Ag], Phosphor P22 Red [Y₂O₂S:Eu], and Phosphor P40 [Gd₂O₂S:Th]; catalyst support sensors: aluminum oxide [Al₂O₃], palladium supported on carbon, and palladium and platinum mixtures and alloys supported on carbon, catalytic dispersions for catalytic reactions: aluminum fluoride [AlF₃], palladium (II) Oxide [PdO], and platinum ruthenium black (for fuel cell applications); ceramics: aluminum oxide [Al₂O₃] for used as a sealant, silica (SiO₂) for use as a ceramic for etch masks, and metal silicates; insulators: magnesium oxide [MgO].

It should be noted that some of the materials noted above comprise new uses made possible by the compositions of the invention. As an example, for CRT applications, phosphors are mostly crystalline, inorganic powders of approximately 5-15 microns in size. For the patterning technology described herein, nanoparticle dispersions of CRT phosphors may be used for flat panel display fabrication. For example, these phosphor materials may be used in the fabrication of field emission displays (FED), plasma display panels (PDP), electroluminescent displays (ELD) and organic light emitting displays (OLEDs).

A further example of a new use for the patterning technology of this invention is the delineation of address electrodes on both anode and cathode plates for FPD pixels and subpixels and other electronic systems requiring electronic addressing capability. Presently, address electrodes for use in FPD's are patterned via a standard photolithographic process. The process employs positive-tone photoresist coated to approximately 1 μm onto a 1200 Å ITO layer previously vapor deposited onto glass. The resist is subsequently patterned via actinic exposure and developed to give the desired pattern of approximately 10 μm resolution. The resulting resist pattern is hard baked and later wet or dry etched to remove the exposed ITO. The hardened resist is finally removed to give the desired ITO address electrode pattern.

It is an object of this invention to eliminate the standard ITO deposition and etch process by using the process of the invention; the patterning formulation itself containing functional ITO nanoparticles, which are directly patterned using standard exposure and develop processes. No etch process is required as a result of the direct patterning process of the invention. The organic components of the ITO nanoparticle formulation (polymer, photochemistry, crosslinkers, additives) are subsequently removed from the ITO film by thermal decomposition at temperatures ≧150° C., depending on the thermal process employed.

As an extension of the above, tin oxide (SnO₂) nanoparticles, because of their increased conductivity relative to ITO, can be similarly patterned into address electrodes on display quality glass. Presently, use of tin oxide as a conductive layer for address electrodes is limited by the inability to etch it effectively, following pattern delineation with resist. Use of the patterning technology and process defined in this invention eliminates the etch step for tin oxide, and ultimately allows its use as a conductive layer for improved conductivity address electrodes in FPDs.

Another example for a new use of the patterning technology of this invention is the direct single-layer patterning of up to 200-micron thick barrier ribs for plasma displays and other electronic devices requiring sequestering of plasmas and/or other high-energy states of matter. For the case of plasma displays, ceramic nanoparticles such as SiO₂ having good heat capacity and high electrical resistance can be formulated with the negative-tone photochemistry of this invention to create in a single-pass coating and patterning process, the desired barrier ribs. Present plasma display barrier rib manufacturing processes use either multiple-pass coating and patterning steps or very crude sand-blasting of screen-printed ceramic films to produce barrier ribs. It is an object of this invention to circumvent the standard process, as it has been found to be inefficient, time-consuming and very expensive.

A further use for the direct patterning technology of this invention is as etch masks for patterning of electronic circuits, such as microelectronic circuits. Use of colloidal silica, or other plasma resistant nanoparticles, such as for example, silicon nitride nanoparticles, formulated with the photochemistry of this invention to provide very thin (<0.05-0.1 μm) highly etch resistant films, can provide superior patterning resolution with very high plasma etch resistance, for the patterning of ultra-fine circuit features, such as gates.

d. Fabrication Procedure

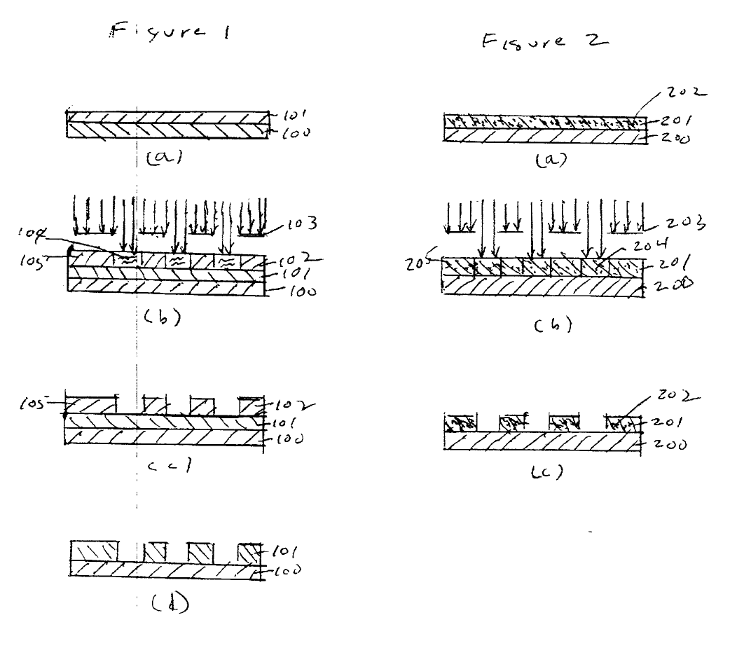

The fabrication of a device in accordance with the invention is represented in FIG. 2 of the drawings. Examples of specific formulations used for the fabrication may be found in the examples. The device fabricated is the same as that illustrated in FIG. 1 of the drawings substituting the process of the invention for the prior art process illustrated in FIG. 1.

In the process depicted in FIG. 2(a), a transparent support 200 is coated with a desired layer of a photopatterning composition to form a continuous film 201 filled with nanoparticles of fluctional material 202. The composition of Example 1 below is a suitable filled photopatterning composition. The method for coating is as described in Example 1. Following formation of film 201, as shown in FIG. 2(b), it would be imaged by exposure to patterned radiation using photomask 203 having opaque and transparent portions to form a latent image within the photoresist coating 201 comprising areas 204 soluble in developer and areas 205 insoluble in developer. Following exposure, photoresist coating 201 would be developed to form a relief image with the insoluble regions 205 remaining as the final coating in a desired patterned coating pattern as shown in FIG. 2(c). If desired, the organic material in photoresist coating 201 may be removed by ablation.

A comparison of the procedures depicted in FIGS. 1 and 2 illustrate the simplicity of the process of the invention compared to the processes of the prior art.

e. Specific Examples

### EXAMPLE 1

Seventy grams of 20 weight-percent ITO dispersion (solution A) (NanoEnergy Corporation) in propylene glycol methyl ether acetate (PGMEA) is combined with thirty grams of 0.2 micron filtered 20 weight-percent solution in PGMEA consisting of 4.8 grams of 2-(2′-furyl ethylidene)-4,6-bis-(trichloromethyl)-s-triazine (TFE); 5.0 grams of a photosensitizer, such as phenothiazine, 49.2 grams of tetrapolymer consisting of 10 mole-percent 2-hydroxypropylmethacrylate (HPMA), 20 mole-percent n-butyl acrylate (nBA), 50 mole-percent methyl methacrylate (MMA), and 20 mole-percent methacrylic acid (MA); 6.0 grams of CYTEC CYMEL 303-ULF melamine crosslinker; 1.2 grams of a 1% solution (in PGMEA) Silwet L7001 leveling agent; all dissolved in 238.8 grams PGMEA (Solution B). The combined solution was rolled milled 1 hour. The material was then filtered through 1 μm coarse glass followed by 1 micron absolute PTFE. Thereafter, the formulation was spin-coated at 4000 rpm for 60 seconds onto 100 mm-diameter Corning 7059-display quality glass and softbaked at 95° C. for 60 seconds. This process provided a coated film thickness of approximately 0.43 μm. The coated glass substrate was then exposed in hard-contact mode using a standard Air Force Mask Target (OPTOLINE Model 4000) using broad band light (365 nm, 8 mW/cm²⁻-second) for 40 seconds (320 mJ/cm²) and post-exposure baked at 100° C. for 120 seconds. The part was subsequently developed (0.14N TMAH) for 60 seconds, rinsed with copious water for 120 seconds and blow-dried. The patterned ITO substrate was found to provide reliable 5 μm negative-tone resolution. The patterned glass was later heated to 600° C. over a 1-hour period to drive off the photochemical components, to leave an intact patterned ITO of approximately 0.2 μm on glass surface.

Processes similar to the above process can be employed to produce ITO electrodes on display quality glass for Flat Panel Displays such as AMLCD, Plasma Displays, Electroluminescent Displays, Organic Light Emitting Displays, and Field Emission Displays.

### EXAMPLE 2

Thirty grams of a 20% solution of Tin Oxide (SnO₂) (10-20 nm monodisperse particles) dispersion in PGMEA was combined with 50 grams of solution B (EXAMPLE 1). The resulting photosensitized dispersion was thereafter filtered and processed in similar fashion to that described in EXAMPLE 1, giving a patterned Tin Oxide surface.

Processes similar to the above can be employed to produce ITO electrodes on display quality glass for Flat Panel Displays such as AMLCD, Plasma Displays, Electroluminescent Displays, Organic Light Emitting Displays, and Field Emission Displays.

### EXAMPLE 3

Thirty grams of a 20% Zn₂SiO₄:Mn (Phosphor P1) dispersion (20 nm monodispersed average particle size) in PGMEA-cyclohexanone was combined with 70 grams of Solution B from EXAMPLE 1. The resulting photosensitized dispersion was thereafter filtered and processed similarly to EXAMPLE 1. A patterned Phosphor P1 phosphor film remained. In this case, the organic materials need not be burned off. A similar process using this and other nanoparticle phosphor dispersions can be employed to produce patterned phosphors on display quality glass for Flat Panel Displays such as Plasma Displays, Electroluminescent Displays, Organic Light Emitting Displays, and Field Emission Displays.

### EXAMPLE 4

Twenty grams of a 20% Aluminum Octoate Al(OH)(C₇H₁₄COO)₂ (25 nm monodisperse particles) dispersion in 3-Ethoxyethylpropionate (EEP)-Cyclohexanone was combined with 80 grams of Solution B from EXAMPLE 1. The whole was filtered and processed similarly to give a patterned aluminum octoate film, which was thereafter thermally processed at 600° C. over a 1-hour period convert the organometallic to zero-valent patterned conductive aluminum.

The above process and similar processes can be used for the production of patterned conductive aluminum surfaces, such as for patterned aluminum conductive reflectors for reflective LCD applications.

### EXAMPLE 5

Ten grams of 20% Palladium (II) Oxide (10-30 nm monodisperse particles) dispersion in EEP-cyclopentanone was combined with 90 grams of Solution B, which was diluted to 10%. The photosensitized dispersion was filtered and processed similarly to give 0.25 μm of patterned PdO film. The film was subsequently heated treated to a range of 400-600° C. to burn off the remaining photochemical components, thus leaving behind a patterned PdO film of approximately 0.1 μm. Similar processes using other nanoparticle dispersions patterned appropriate to the application, can be used to produce other heterogeneous catalytic surfaces for microfluidic organic syntheses.

### EXAMPLE 6

Forty grams of 20% Magnesium Oxide (MgO) (20 nm monodisperse particles) dispersion in PGMEA was combined with sixty grams of Solution B from EXAMPLE 1. The combined solution was filtered and processed in similar fashion as in EXAMPLE 1 to give 5 μm resolution patterned MgO film of approximately 0.6 μm. The film was subsequently heated to 500° C. for 2 hours to remove residual photochemical components, thus leaving patterned MgO. This and similar processes can be used to pattern magnesium oxide insulating layers for Plasma Displays.

### EXAMPLE 7

Sixty grams of a 40% colloidal silica dispersion (10 nm monodisperse) in EEP/Cyclohexanone is combined with forty grams of 1 μm PTFE filtered 40% solution consisting of 7.0 grams Irgacure 291 (PAG), 73.0 grams EPON SU-8 epoxynovolak polymer, 7.0 grams of 1% Silwet L7001 in EEP, and 89.5 grams EEP, and 29.8 grams Cyclohexanone (C). The whole was filtered through 1 micron coarse glass and 1 micron absolute PTFE. A film thickness of approximately 300 μm was cast using slot or screen coating techniques, followed by softbaking at 80° C. for 30-50 minutes in a forced hot air convection oven, or using an IR bake track set for conditions providing equivalent solvent removal. The film was then exposed using conditions similar to those listed in EXAMPLE 1 above. Exposure was followed by a post-exposure bake at 100° C. for 5-30 minutes in a forced air convection oven or using an IR bake track set to provide equivalent photospeed to the convection oven PEB condition. Thereafter, the exposed part was developed in 0.14N TMAH for 60 seconds, followed by a 120-second rinse with copious water spray. The patterned thus rendered gave 20 μm best resolution. The patterned glass was then baked at 600° C. for 1-2 hours to remove residual photochemistry, thus leaving the patterned silica behind. This and similar processes, using suitable dispersions, can be used to fabricate barrier ribs for plasma and field emission displays. This process, using nanoparticle fillers appropriate to the specific application, may also be used to pattern directly, three-dimensional (3-D) functional structures for MEMS devices.

1. A method for forming one or more patterned layers of functional material over a substrate, said method comprising providing a coating composition comprising a photopatterning material containing a particulate filler of a functional material, said particulate filler being essentially transparent to activating radiation, coating said coating composition over at least a portion of the substrate, exposing said coating to activating radiation in an image pattern, and developing said coating to form said patterned layer of functional material.

2. The method of claim 2 where the mean diameter of the particulate filler has a mean diameter of less than about 100 nm.

3. The method of claim 2 where the mean diameter is less than about 50 nm.

4. The method of claim 2 where the mean diameter varies between about 5 and 40 nm.

5. The method of claim 2 where the total surface area of the particles comprising the particulate filler varies between 30 and 1,000 m²/g.

6. The method of claim 1 where the filler is contained within the photopatterning composition in an amount of up to 90 percent by weight of the composition.

7. The method of claim 1 where the filler is contained within the photopatterning composition in an amount of from 25 to 80 percent by weight of the composition.

8. The method of claim 2 where the filler is a material selected from the group consisting essentially of a semiconductor, a conductor, a phosphor, a catalyst, a ceramic, a sealant, and an insulator.

9. The method of claim 8 where the filler is a semiconductor.

10. The method of claim 9 where the filler is an indium tin oxide.

11. The method of claim 9 where the filler is a tin oxide.

12. The method of claim 8 where the filler is a phosphor.

13. The method of claim 1 including a step of removing a major portion of the organic components of the photopatterning composition from the coating following the steps of exposure and development.

14. A method for making an active matrix liquid crystal display, said method comprising providing a coating composition comprising a photopatterning material containing a particulate filler of a functional material, said particulate filler having a mean diameter of less than about 100 nm and a total surface area between 50 and 1,000 m²/g, coating said photopatterning composition over at least a portion of the substrate, exposing said coating to activating radiation in an image pattern, and developing said coating to form said patterned layer of functional material.

15. The method of claim 14 where the mean diameter of the particulate filler varies between about 5 and 40 nm.

16. The method of claim 14 where the particulate filler is contained within the photopatterning composition in an amount of up to 90 percent by weight of the total composition.

17. A photopatterning composition filled with a particulate filler, said filler comprising particles having a mean diameter whereby the particles are essentially transparent to activating radiation for the photopatterning composition and contained within the photopatterning composition in an amount of up to 90 percent by weight of the total composition.

18. The composition of claim 17 where the mean diameter of the particulate filler is less than about 100 nm.

19. The composition of claim 18 where the mean diameter of the particulate filler varies between about 5 and 40 nm.

20 The composition of claim 17 where the particulate filler is a material selected from the group consisting essentially of a semiconductor, a phosphor, a catalyst, a ceramic, a sealant, and an insulator.
